(19) United States
(12) Patent Application Publication
(10) Pub. No.: US 2009/0015341 A1
(43) Pub. Date: Jan. 15, 2009

(54) Piezoelectric oscillator

(76) Inventor: Tomio Satoh, Tokyo (JP)

Correspondence Address: Koda & Androlia, 2029 Century Park East, Suite 1140, Los Angeles, CA, 90067-2983, US

(21) Appl. No.: 11/665,044

(22) PCT Filed: Oct. 12, 2005
(86) PCT No.: PCT/JP05/18820

§ 371 Date: Apr. 10, 2007

(30) Foreign Application Priority Data
Oct. 12, 2004 (JP) 2004-297669

(51) Int. Cl. H03B 5/36

(52) U.S. Cl. 331/116 R

(57) ABSTRACT

In order to remove external noise of the same phase, such as a power supply noise, on an crystal oscillator, one oscillation output has been conventionally obtained from one oscillation circuit, and by using a differential amplifier, the one oscillation output is turned into two oscillation outputs that are 180 degrees out of phase. However, it has been impossible to remove the noise of the same phase that occurs in the oscillation circuit. According to the present invention, there is provided a piezoelectric oscillator including a piezoelectric vibrator, and first and second oscillation circuits, and comprising a configuration such that an input terminal of the first oscillation circuit and one terminal of the piezoelectric vibrator are connected, an input terminal of the second oscillation circuit and the other terminal of the piezoelectric vibrator are connected, characterized in that: oscillation outputs that are 180 degrees out of phase to each other are obtained from outputs of the first and second oscillation circuits.

### TECHNICAL FIELD

The present invention relates to a piezoelectric oscillator, and, more particularly to a piezoelectric oscillator used for a base station device of a high speed data communication or the like, a reference-frequency generating device of a measuring instrument or the like, a communication device of a mobile object or the like, that requires reduction in noise, and other devices.

### BACKGROUND ART

In voltage controlled crystal oscillators VCXO (Voltage Controlled Xtal OSC) used in a high speed communication or the like, when data is transferred, oscillation circuits capable of producing two oscillation outputs that are 180 degrees out of phase to enable a transfer at low noise are used.

FIG. 10 shows a conventional technique.

An oscillation circuit shown in FIG. 10 includes a grounded-base amplifier having a configuration such that one oscillation output from the oscillation circuit is inputted to a base of a transistor TR2, and a configuration such that a base of a transistor TR3 whose emitter is commonly connected to an emitter of the transistor TR2 is AC-wise grounded. One oscillation output is obtained from a collector of the transistor TR3. Further, one oscillation output is obtained from a collector of the transistor TR2. The two oscillation outputs are the same in frequency and 180 degrees out of phase to each other. The oscillation circuit is configured such that an output signal from the transistor TR2 and an output signal from the transistor TR3 are inputted to a matching circuit to obtain an oscillation output of an oscillator circuit.

FIG. 11 shows an example of an oscillation circuit as a differential amplifier, in which IC dedicated to a high speed data communication, such as PECL IC and LVDS IC, is used. Generally, the IC includes therein a circuit in which differential amplifiers are connected in a multistage manner.

Also in this case, the differential amplifier on the first stage is used to obtain two outputs that are 180 degrees out of phase as in the case of the circuit shown in FIG. 10. Patent Document 1: Japanese Patent Application Laid-open No. 2004-104720

### DISCLOSURE OF THE INVENTION

### Problems to be Solved by this Invention

In conventional crystal oscillators, one oscillation output obtained from one oscillation circuit is used to obtain two oscillation outputs that are 180 degrees out of phase by using the differential amplifier.

Accordingly, the original purpose of obtaining the two outputs is to remove external noise of the same phase, such as a power supply noise, on the crystal oscillator by using a differential amplifier on a later stage. However, as set forth above, needless to say, it has been impossible to remove the noise of the same phase occurring in the oscillation circuit by one oscillation output.

Accordingly, in the present invention, it is an object thereof to provide a piezoelectric oscillation circuit capable of producing, as an oscillator output, two outputs that are 180 degrees out of phase and the same in waveform, outputted from one oscillation loop. Further, it is an object of the present invention to provide a piezoelectric oscillation circuit including a circuit that removes noise of the same phase by arranging, if needed, a differential amplifier inside of the oscillator.

### Means for Solving the Problems

To achieve the above objects, the present invention provides a piezoelectric oscillator including a piezoelectric vibrator, and first and second oscillation circuits, and comprising a configuration such that an input terminal of the first oscillation circuit and one terminal of a piezoelectric vibrator are connected, an input terminal of the second oscillation circuit and the other terminal of a piezoelectric vibrator are connected, characterized in that oscillation outputs that are 180 degrees out of phase to each other are obtained from outputs of the first and second oscillation circuits. The invention further provides a piezoelectric oscillator comprising a differential amplifier having two input terminals to which each output of the first and second oscillation circuits is inputted, a piezoelectric oscillator comprising a high speed data transfer-use IC configured by a differential amplifier pair to which each output of the first and second oscillation circuits is inputted, and a piezoelectric oscillator characterized in that one output is obtained via a common mode transformer used for removing noise of the same phase, to which each output of the first and second oscillation circuits is inputted, and a transformer to which an output of the common mode transformer is inputted. The invention further provides a piezoelectric oscillator including a piezoelectric vibrator, a first oscillation circuit, and a second oscillation circuit, characterized in that the first oscillation circuit is a Colpitts oscillation circuit including a configuration such that a first capacitor is connected between a first transistor and a base and an emitter of the first transistor, and a configuration such that a second capacitor is connected between the emitter and a ground; the second oscillation circuit is a Colpitts oscillation circuit including a configuration such that a third capacitor is connected between a second transistor and a base and an emitter of the transistor, and a configuration such that a fourth capacitor is connected between the emitter and a ground; there is included a configuration such that one end side of the piezoelectric vibrator is connected to the base of the first transistor and the other one end of the piezoelectric vibrator is connected to the base of the second transistor; and in order to obtain oscillation outputs that are 180 degrees out of phase to each other from outputs of the first and second oscillation circuits, both of a transistor terminal, which is an output terminal of the first oscillation circuit, and a transistor terminal, which is an output terminal of the second oscillation circuit, are the same location.

### EFFECT OF THE INVENTION

According to the present invention, it is possible to obtain, with a high level of accuracy, two oscillation outputs that are of the same waveform and 180 degrees out of phase, which has been impossible to achieve in the conventional technique.

According to the present invention, since it is possible to remove noise of the same phase from an oscillation output by using a differential amplifier or the like, hence possible to achieve high performance of the piezoelectric oscillator, resulting in providing great merits to devices that use the oscillator, a mobile communication apparatus or the like.

### BEST MODE FOR CARRYING OUT THE INVENTION

Embodiments of the present invention will be explained below in detail.

FIG. 1 is a circuit diagram showing a first embodiment of a voltage controlled crystal oscillator according to the present invention.

The crystal oscillator includes a first oscillation circuit OSC1, a second oscillation circuit OSC2, and a crystal vibrator Xtal.

Both of the first and second oscillation circuits substantially have the same configuration as that of the conventional oscillation circuit (the oscillation circuit portion in FIGS. 10 and 11) that uses transistors.

The crystal oscillator includes a configuration such that an input terminal of the first oscillation circuit OSC1 and one terminal of the crystal vibrator Xtal are connected, and a configuration such that the other terminal of the crystal vibrator Xtal and the second oscillation circuit OSC2 are connected via a voltage control circuit.

The voltage control circuit includes a circuit in which the crystal vibrator Xtal, a variable capacitance diode D1 that changes an oscillation frequency, and a capacitor C7 that adjusts an oscillation frequency are connected in series, a reference voltage circuit configured such that a connection point of the variable capacitance diode D1 and the capacitor C7 is grounded via a resistance R9, and a control voltage applying circuit configured such that a connection point of the variable capacitance diode D1 and the crystal vibrator Xtal is applied a control voltage via a resistance R8.

A characteristic configuration of the present invention is that the crystal vibrator Xtal is inserted and connected between the input terminal of the first oscillation circuit OSC1 and the input terminal of the second oscillation circuit OSC2, and as shown by a dotted line in FIG. 1, one oscillation loop is configured by overlapping the two oscillation circuits so as to function as an oscillation circuit.

It is noted that in this embodiment, the crystal oscillator based on the present invention is the voltage controlled crystal oscillator in which the voltage control circuit is inserted between the crystal vibrator and the input terminal of the second oscillation circuit OSC2.

However, the crystal oscillator based on the present invention can be a circuit configuration in which the voltage control circuit shown in FIG. 1 is omitted and the crystal vibrator is inserted and connected between the two oscillation circuits.

In short, in the crystal oscillator based on the present invention, what is important is that an alternating current flows to a ground from a base of a transistor TR1 via an emitter thereof, for example, and the alternating current flows from a ground of a transistor TR2 to the side of a base of the transistor TR2 via a capacitor C3, thereby configuring one closed circuit loop through a channel, that is, from the capacitor C7→the variable capacitance diode D1→the crystal vibrator Xtal→the base of the transistor TR1.

The point that should be noted is that a voltage output that occurs in a collector resistance R1 of the transistor TR1 and a voltage output that occurs in a collector resistance R5 of the transistor TR2 are 180 degrees out of phase.

FIG. 2 is a diagram showing a n-type equivalent circuit of the crystal oscillator according to the present invention shown in FIG. 1.

Rπ1 and Rπ2 denote equivalent resistances between the base and the emitter of the transistors TR1 and TR2. Cπ1 and Cπ2 denote junction capacitances between the base and the emitter of the transistors TR1 and TR2. Cx denotes variable capacitances of the variable capacitance diode D1 and the capacitor C7 in FIG. 1.

A relationship of a current of the equivalent circuit shown in FIG. 2 provides Equation (1) and Equation (2). A relationship of a voltage thereof provides Equation (3).

i₂=(1+gₘ₁z₁)iₓ (1)

i₄=(1+gₘ₂z₃)iₓ (2)

z₄i₄=(z₃+zₓₜz₁)iₓ+z₂i₂ (3)

Substitute Equation (1) and Equation (2) into Equation (3), and eliminate iₓ to obtain Equation (4).

z₄(1+gₘ₂z₃)+zₓₜ+z₁z₂(1+gₘ₁z₁)=0 (4)

Rearrange Equation (4) to obtain Equation (5). Equation (5) is a basic equation of the circuit.

zₓₜ+z₁+z₂+z₃+z₄+gₘ₁z₁z₂+gₘ₂z₃z₄ (5)

Assume that the completely same transistors, and the identical resistances and the capacitors are used in the first oscillation circuit OSC1 and the second oscillation circuit OSC2, Equation (6) holds.

z₁=z₃ gₘ₁=gₘ₂ z₂=z₄ (6)

Substitute Equation (6) into Equation (5) to obtain Equation (7).

zₓₜ+2(z₁+z₂+gₘ₁z₁z₂)=0 (7)

Replace Equation (7) with Zₓₜ, a circuit resistance R_{c2}, and a capacitive reactance of the circuit C_{c2} to obtain Equation (8).

$${z}_{xt} + {R}_{c 2} + \frac{1}{j {ω}_{os} {C}_{c 2}} = 0 \qquad ( 8 )$$

The resistance R_{c2} of the circuit is expressed by Equation (9). The capacitive reactance C_{c2} is expressed by Equation (10).

$$\begin{matrix}{R}_{c 2} = 2 ( {r}_{1} + {r}_{2} + {g}_{m 1} {r}_{1} {r}_{2} - \frac{{g}_{m 1}}{{ω}_{os}^{2} {c}_{1} {c}_{2}} ) & ( 9 ) \\ \frac{1}{{C}_{c 2}} = 2 ( \frac{1 + {g}_{m 1} {r}_{2}}{{c}_{1}} + \frac{1 + {g}_{m 1} {r}_{1}}{{c}_{2}} ) & ( 10 )\end{matrix}$$

An oscillation circuit portion of the conventional circuit is similarly analyzed for comparison.

FIG. 12 is a diagram showing a π-type equivalent circuit of the oscillation circuit portion of the conventional circuit shown in FIG. 10 and FIG. 11.

A negative resistance R_{c} of the circuit viewed from the side of a vibrator zₓₜ of the same circuit can be evaluated according to Equation (11).

Further, a capacitive reactance C_{c} of the same circuit can be evaluated according to Equation (12).

$$\begin{matrix}{R}_{c} = {r}_{1} + {r}_{2} + {g}_{m 1} {r}_{1} {r}_{2} - \frac{{g}_{m 1}}{{ω}_{os}^{2} {c}_{1} {c}_{2}} & ( 11 ) \\ \frac{1}{{C}_{c}} = \frac{1 + {g}_{m 1} {r}_{2}}{{c}_{1}} + \frac{1 + {g}_{m 1} {r}_{1}}{{c}_{2}} \\ ∵ {r}_{1} = \frac{{R}_{π}}{1 + {\{ {ω}_{os} ( {C}_{π 1} + {C}_{1} ) {R}_{π 1} \}}^{2}} , \\ {c}_{1} = \frac{1}{{ω}_{os}^{2} {C}_{π} {R}_{π} {r}_{1}} \\ {r}_{2} = \frac{{R}_{2}}{1 + {( {ω}_{os} {C}_{2} {R}_{2} )}^{2}} , \\ {c}_{2} = \frac{1}{{ω}_{os}^{2} {C}_{2} {R}_{2} {r}_{2}} & ( 12 )\end{matrix}$$

FIG. 3 is a graph in which simulation results using these equations are compared.

A comparison between a result of the resistance R_{c} in Equation (11) and the capacitive reactance C_{c} in Equation (12) in the conventional circuit, and a result of the resistance R_{c2} in Equation (9) and the capacitive reactance C_{c2} in Equation (10) in the present invention shows that the resistance R_{c2} is two times as large as the resistance R_{c} and the capacitive reactance C_{c2} is half the capacitive reactance C_{c}.

In order to verify the results of the simulation by using these equations, an experiment was conducted by using a circuit shown in FIG. 4.

Assume that transistors and circuit constants of first and second oscillation circuits OSC1 and OSC2 are the same. Assume that a power supply voltage be 5V. A crystal vibrator used herein is an At-Cut crystal vibrator whose first frequency is 23 MHz. A crystal oscillator is configured such that the crystal vibrator is inserted and connected between bases of the OSC1 and the OSC2.

FIG. 5 is a graph showing collector waveform outputs of the experimental circuit, observed with an oscilloscope.

The graph shows that the waveforms are clipped and distorted waveforms, but confirms that oscillation outputs of the first and second oscillation circuits OSC1 and OSC2 are 180 degrees out of phase.

FIG. 6 is a graph showing emitter waveform outputs of the experimental circuit, observed with an oscilloscope.

The graph shows that the waveforms have few distortions, and obviously shows that the two outputs are 180 degrees out of phase.

FIG. 7 is a circuit diagram showing a second embodiment of a voltage controlled crystal oscillator according to the present invention.

An oscillation circuit portion of the circuit is configured such that two oscillation outputs from the oscillation circuit portion are connected to two input terminals of a differential amplifier on a subsequent stage, as in the case of the configuration in FIG. 1. The crystal oscillator is configured such that noise of the same phase of the oscillation output is removed by the differential amplifier, and thereafter, the oscillation output is outputted via an external matching circuit on a subsequent stage.

FIG. 8 is a circuit diagram showing a third embodiment of a crystal oscillator according to the present invention.

In this circuit, instead of the differential amplifier in the second embodiment, a high speed data communication-use differential amplifier IC, such as PECL (=Positive Emitter Coupled Logic) or LVDS (=Low Voltage Differential Signaling) or the like, is used.

FIG. 9 is a circuit diagram showing a fourth embodiment of a voltage controlled crystal oscillator according to the present invention.

This circuit is configured such that instead of the differential amplifier in the second embodiment, a common mode transformer T1 is used to remove noise of the same phase from an oscillation output, and thereafter, a transformer T2 on a subsequent stage is used to obtain one oscillation output.

It is noted that in this embodiment, the crystal vibrator is used. However, the present invention is not limited to this, and can be applied to a circuit in which another piezoelectric vibrator is used.

### BRIEF DESCRIPTION OF THE DRAWINGS

FIG. 1 is a circuit diagram showing a first embodiment of a voltage controlled crystal oscillator according to the present invention.

FIG. 2 is a diagram showing a π-type equivalent circuit of an oscillation circuit according to the present invention shown in FIG. 1.

FIG. 3 is a graph in which simulation results are compared.

FIG. 4 is a diagram showing an experimental circuit.

FIG. 5 is a waveform chart in which collector waveform outputs of the experimental circuit are observed with an oscilloscope.

FIG. 6 is a waveform chart in which emitter waveform outputs of the experimental circuit are observed with an oscilloscope.

FIG. 7 is a circuit diagram showing a second embodiment of a voltage controlled crystal oscillator according to the present invention.

FIG. 8 is a circuit diagram showing a third embodiment of a crystal oscillator according to the present invention.

FIG. 9 is a circuit diagram showing a fourth embodiment of a voltage controlled crystal oscillator according to the present invention.

FIG. 10 is a circuit diagram showing a conventional crystal oscillator.

FIG. 11 is a circuit diagram showing a conventional crystal oscillator.

FIG. 12 is a diagram showing a π-type equivalent circuit of an oscillation circuit portion of FIG. 10 and FIG. 11.

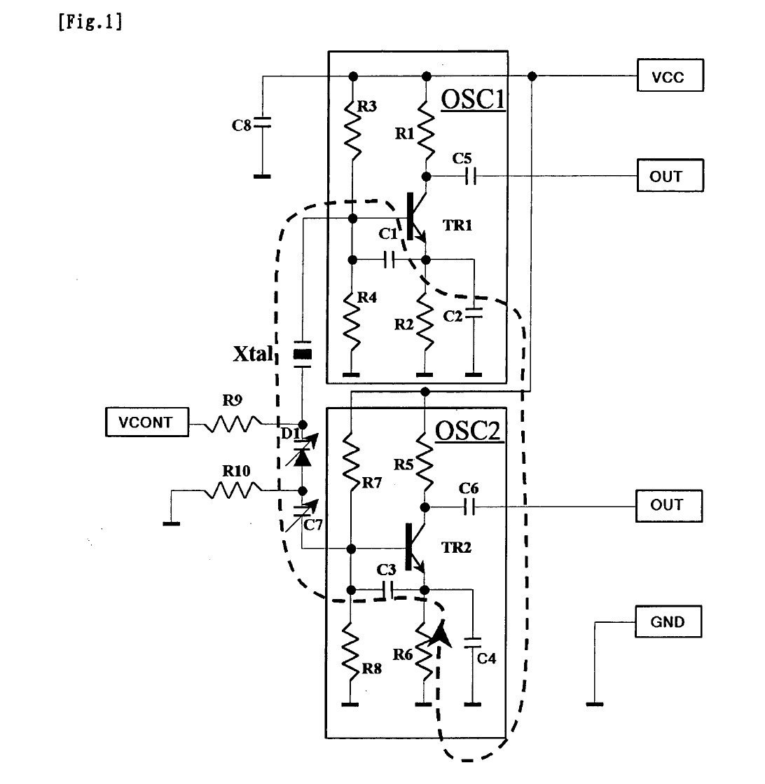

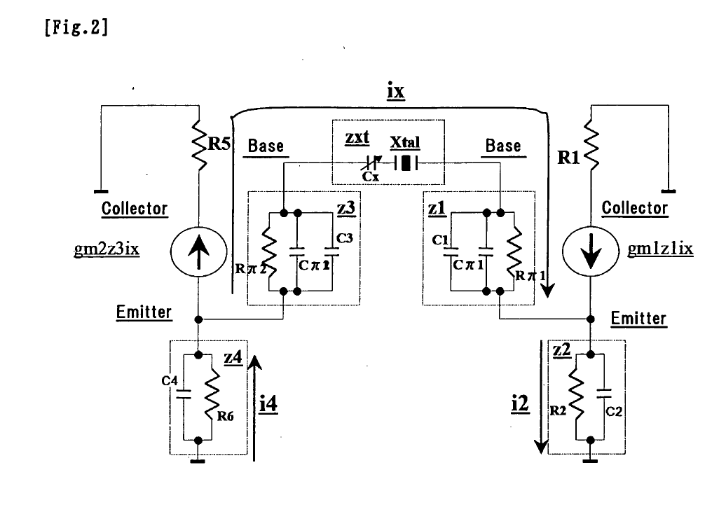

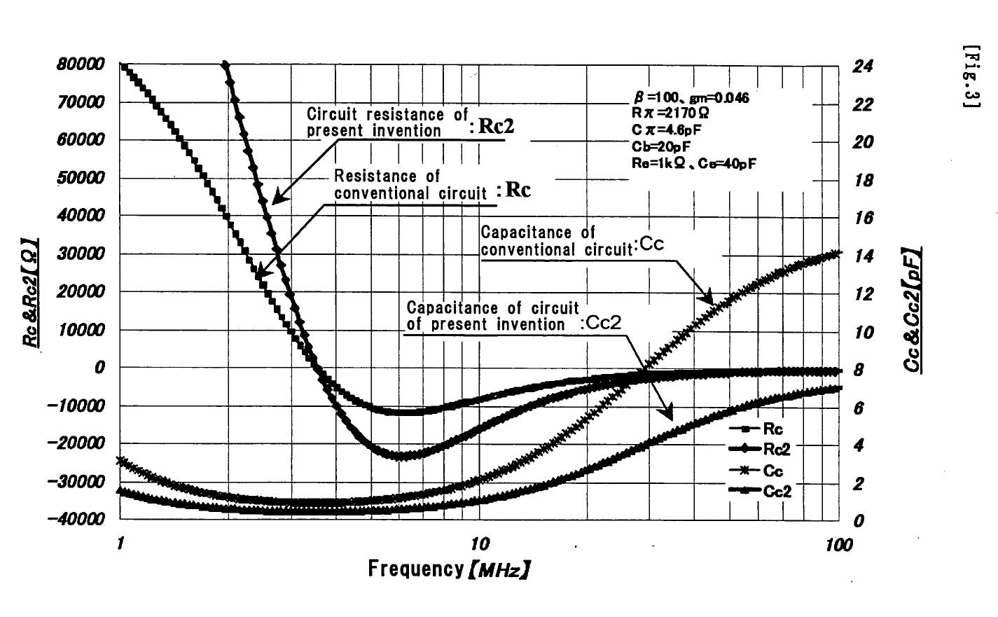

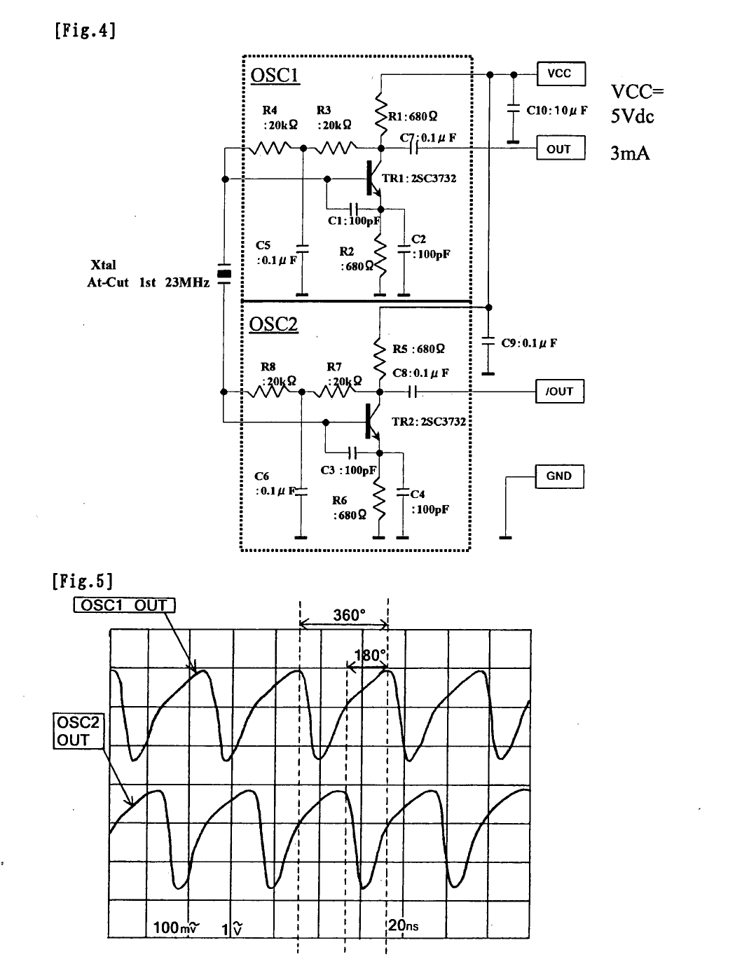

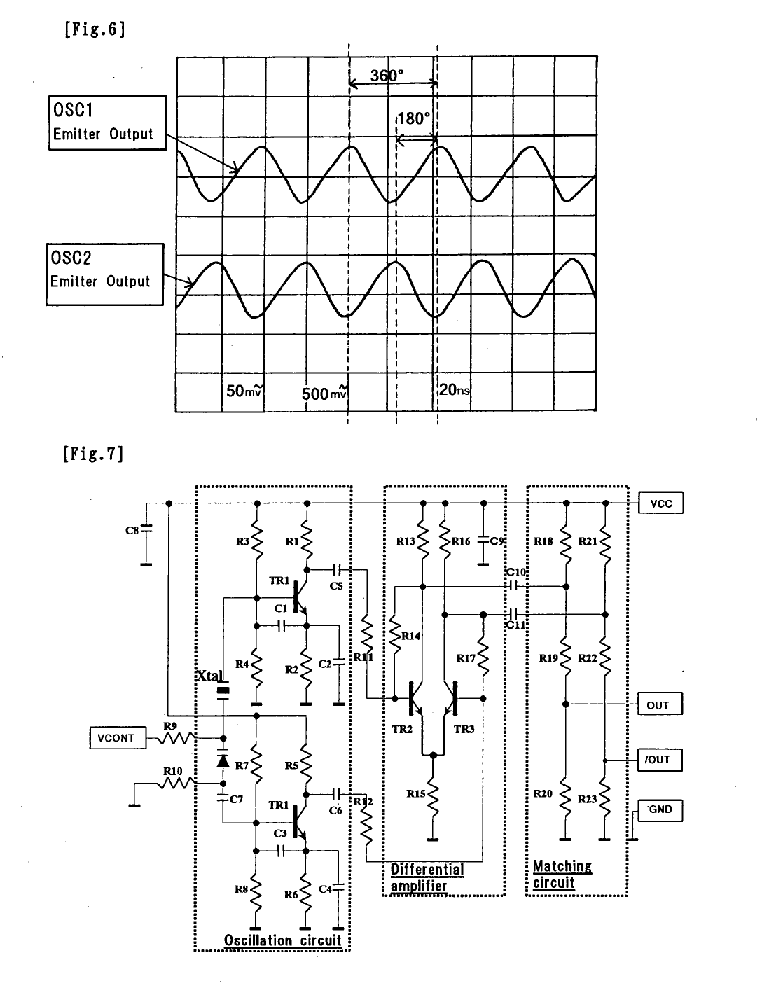

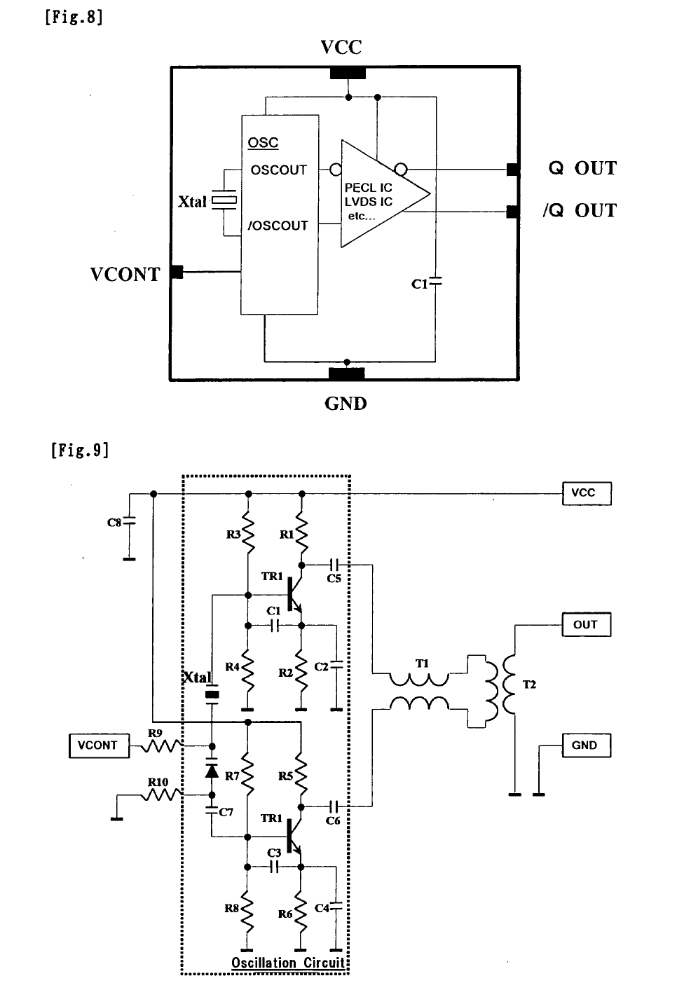

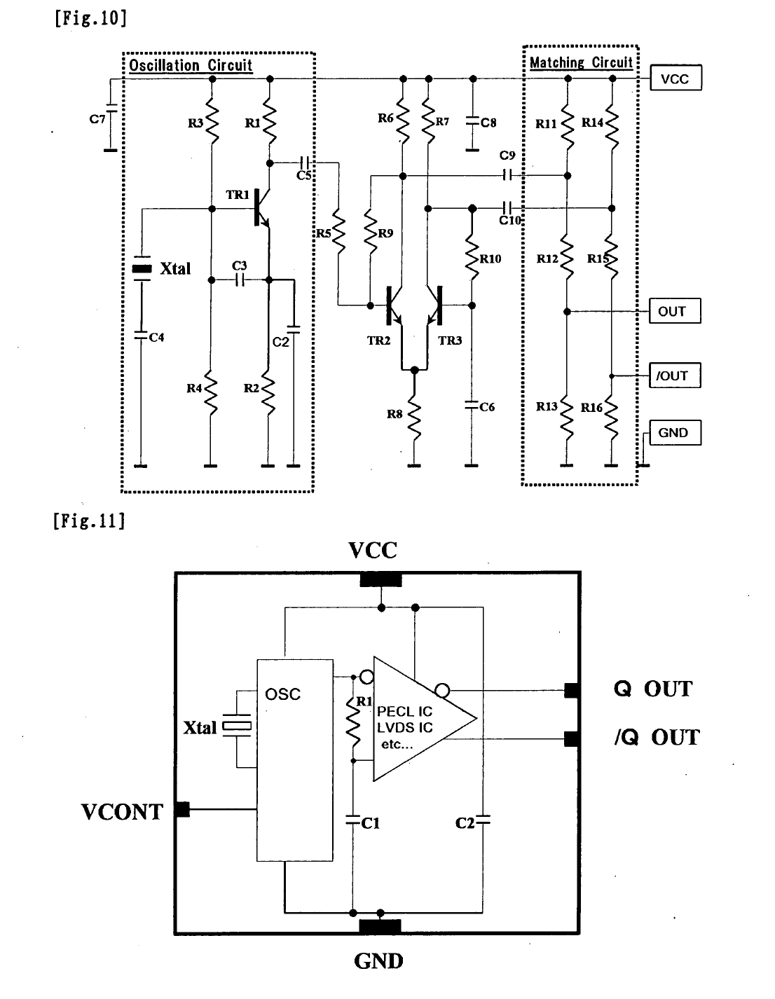

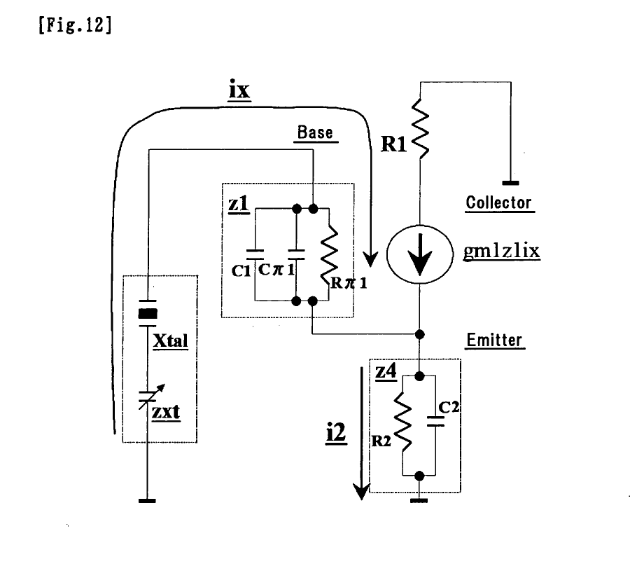

### EXPLANATION OF THE CODES

Xtal . . . Crystal vibrator
OSC1 . . . First oscillation circuit
OSC2 . . . Second oscillation circuit
T1 . . . . Common mode transformer
T2 Transformer

1. A piezoelectric oscillator including a piezoelectric vibrator, and first and second oscillation circuits, comprising: a configuration such that an input terminal of said first oscillation circuit and one terminal of said piezoelectric vibrator are connected, an input terminal of said second oscillation circuit and the other terminal of said piezoelectric vibrator are connected, and said first and second oscillation circuits are connected to the same power supply, characterized in that: said power supply is simultaneously applied to said first and second oscillation circuits; and oscillation outputs that are 180 degrees out of phase to each other are obtained from outputs of said first and second oscillation circuits.

2. The piezoelectric oscillator according to claim 1, comprising a differential amplifier having two input terminals to which each output of said first and second oscillation circuits is inputted.

3. The piezoelectric oscillator according to claim 1, comprising a high speed data transfer-use IC configured by a differential amplifier pair to which each output of said first and second oscillation circuits is inputted.

4. The piezoelectric oscillator according to claim 1, characterized in that: one output is obtained via a common mode transformer used for removing noise of the same phase, to which each output of said first and second oscillation circuits is inputted, and a transformer to which an output of the common mode transformer is inputted.

5. A piezoelectric oscillator including a piezoelectric vibrator, a first oscillation circuit, and a second oscillation circuit, characterized in that: said first oscillation circuit is a Colpitts oscillation circuit including a configuration such that a first capacitor is connected between a base and an emitter of a first transistor, and a configuration such that a second capacitor is connected between said emitter and a ground; said second oscillation circuit is a Colpitts oscillation circuit including a configuration such that a third capacitor is connected between a second tar a base and an emitter of a second transistor, and a configuration such that a fourth capacitor is connected between said emitter and a ground; there is included a configuration such that one end side of said piezoelectric vibrator is connected to the base of said first transistor and the other end of the piezoelectric vibrator is connected to the base of said first transistor; and in order to obtain oscillation outputs that are 180 degrees out of phase to each other from outputs of said first and second oscillation circuits, both of a transistor terminal, which is an output terminal of said first oscillation circuit, and a transistor terminal, which is an output terminal of said second oscillation circuit, are the same location.
